(19) United States
(12) Patent Application Publication
(10) Pub. No.: US 2025/0151499 A1
(43) Pub. Date: May 8, 2025

(54) DISPLAY SUBSTRATE AND METHOD FOR PREPARING THE DISPLAY SUBSTRATE, DISPLAY PANEL, AND DISPLAY DEVICE

(71) Applicants: Yunnan Invensight Optoelectronics Technology Co., Ltd., Kunming, Yunnan (CN); BOE Technology Group Co., Ltd., Beijing (CN)

(72) Inventors: Yunlong LI, Beijing (CN); Pengcheng LU, Beijing (CN); Wei LIU, Beijing (CN); Xiao BAI, Beijing (CN)

(21) Appl. No.: 18/832,945

(22) PCT Filed: Sep. 26, 2023
(86) PCT No.: PCT/CN2023/121538

§ 371 Date: Jul. 25, 2024

(30) Foreign Application Priority Data
Oct. 31, 2022 (CN) 202211348655.9

(51) Int. Cl. H10H 29/49; H01L 25/075; H10H 20/816; H10H 29/01; H10H 29/14; H10H 29/37

(52) U.S. Cl. CPC H10H 29/49; H01L 25/0753; H10H 20/816; H10H 29/012; H10H 29/14; H10H 29/37

(57) ABSTRACT

Provided is a display substrate, including an array substrate, a connection layer, and a light-emitting functional layer, wherein the connection layer is disposed between the array substrate and the light-emitting functional layer; and the connection layer is provided with a plurality of via holes, and the light-emitting functional layer comprises a plurality of light-emitting units, wherein each of the light-emitting units is electrically connected with a conductive structure in at least one via hole, and an orthographic projection of the via hole on a carrying surface of the connection layer is disposed outside an orthographic projection of a light-emitting region of a corresponding light-emitting unit on the carrying surface.

### CROSS-REFERENCE TO RELATED APPLICATIONS

The present disclosure is a U.S. national phase application based on PCT/CN2023/121538, filed on Sep. 26, 2023, which is based on and claims priority to Chinese Patent Application No. 202211348655.9, filed on Oct. 31, 2022 and entitled “DISPLAY SUBSTRATE AND METHOD FOR PREPARING THE DISPLAY SUBSTRATE, DISPLAY PANEL, AND DISPLAY DEVICE”, the content of which is herein incorporated by reference in its entirety.

### TECHNICAL FIELD

The present disclosure relates to the field of display technologies, and in particular, relates to a display substrate and a method for preparing the display substrate, a display panel, and a display device.

### BACKGROUND

The display substrate generally includes an array substrate, a connection layer, and a light-emitting functional layer which are sequentially stacked. The connection layer is provided with a plurality of via holes, and the via holes are connected between the array substrate and the light-emitting functional layer. Each of the via holes is connected with one light-emitting unit in the light-emitting functional layer.

### SUMMARY

Embodiments of the present disclosure provide a display substrate and a method for preparing the display substrate, a display panel, and a display device. The technical solutions are as follows.

The embodiments of the present disclosure provide a display substrate, including: an array substrate, a connection layer, and a light-emitting functional layer, wherein the connection layer is disposed between the array substrate and the light-emitting functional layer; and the connection layer is provided with a plurality of via holes, and the light-emitting functional layer includes a plurality of light-emitting units, wherein each of the light-emitting units is electrically connected with a conductive structure in at least one via hole, and an orthographic projection of the via hole on a carrying surface of the connection layer is disposed outside an orthographic projection of a light-emitting region of a corresponding light-emitting unit on the carrying surface.

In some embodiments, the light-emitting functional layer further includes a pixel definition layer, the pixel definition layer including a plurality of openings spaced apart from each other, wherein the openings are in one-to-one correspondence with the light-emitting units, and each of the light-emitting units is disposed in a corresponding opening; and each of the openings is configured to define the light-emitting region of the corresponding light-emitting unit.

In some embodiments, the plurality of the light-emitting units are arranged in an array along a first direction and a second direction, the first direction being intersected with the second direction; and the plurality of the light-emitting units include a plurality of first light-emitting unit groups and a plurality of second light-emitting unit groups which are sequentially and alternately arranged along the second direction, and each of the first light-emitting unit groups and the second light-emitting unit groups includes a plurality of the light-emitting units which are spaced apart from each other along the first direction; wherein a plurality of the via holes corresponding to the first light-emitting unit group are disposed on the same side of the first light-emitting unit group, and a plurality of the via holes corresponding to the second light-emitting unit group are disposed on the same side of the second light-emitting unit group.

In some embodiments, in adjacent first light-emitting unit group and second light-emitting unit group, the via holes corresponding to the first light-emitting unit group and the via holes corresponding to the second light-emitting unit group are disposed at both sides of the first light-emitting unit group or the second light-emitting unit group.

In some embodiments, in adjacent first light-emitting unit group and second light-emitting unit group, the via holes corresponding to the first light-emitting unit group and the via holes corresponding to the second light-emitting unit group are disposed between the first light-emitting unit group and the second light-emitting unit group.

In some embodiments, each of the light-emitting units includes an anode layer and a light-emitting layer which are sequentially stacked, wherein the anode layer is disposed on the carrying surface, the pixel definition layer is disposed on the carrying surface and the anode layer, a portion of a surface of the anode layer is exposed from the openings of the pixel definition layer, and the light-emitting layer is disposed in the openings; and the via hole is connected with the anode layer, and the orthographic projection of the via hole on the carrying surface is disposed in an orthographic projection of the pixel definition layer on the carrying surface.

In some embodiments, each of the light-emitting units further includes a current spreading layer, wherein the current spreading layer is disposed between the anode layer and the light-emitting layer.

In some embodiments, a maximum length of a portion of the pixel definition layer on the anode layer in a direction from an edge of the anode layer to a middle of the anode layer is not less than 0.2 μm.

In some embodiments, isolation grooves are arranged in the pixel definition layer, wherein the isolation grooves divide the pixel definition layer into a plurality of pixel regions, one of the light-emitting units being arranged in each of the pixel regions.

In some embodiments, each of the isolation grooves at least includes a first portion and a second portion which are connected with each other, wherein the first portion and the second portion are sequentially arranged along a direction away from the carrying surface, and a dimension of the first portion in an arrangement direction of two light-emitting units adjacent to the isolation groove is not smaller than a dimension of the second portion in the arrangement direction of the two light-emitting units adjacent to the isolation groove.

In some embodiments, a groove depth of the isolation groove is not less than a thickness of the light-emitting layer.

In some embodiments, in a same pixel region, the via hole is located between the isolation groove and the light-emitting region.

In some embodiments, in the same pixel region, a minimum distance between a geometric center of the via hole and the light-emitting region is smaller than a minimum distance between the geometric center of the via hole and the isolation groove.

In some embodiments, in two adjacent pixel regions in the second direction, a distance between geometric centers of two via holes is greater than a pitch between two light-emitting regions.

In some embodiments, in two adjacent pixel regions in the second direction, a distance between geometric centers of two via holes is smaller than a distance between geometric centers of two light-emitting regions.

In some embodiments, regions of the film layers of the light-emitting functional layer which are opposite to a plurality of the via holes protrude from surfaces, facing away from the carrying surface, of the film layers of the light-emitting functional layer, or are recessed from the surfaces, facing away from the carrying surface, of the film layers of the light-emitting functional layer.

In some embodiments, the conductive structure in the via hole is a tungsten structure.

In some embodiments, the display substrate further includes a color film layer, wherein the light-emitting unit is a white light pixel unit, and the color film layer is disposed on the light-emitting functional layer.

The embodiments of the present disclosure provide a display panel, including the display substrate described above, a touch layer, and a packaging layer, wherein the display substrate, the touch layer, and the packaging layer are sequentially stacked.

The embodiments of the present disclosure provide a display device, including the display panel described above and a power supply electrically connected with the display panel.

The embodiments of the present disclosure provide a method for preparing a display substrate, including: preparing an array substrate; forming a connection layer on the array substrate, wherein the connection layer is provided with a plurality of via holes; and forming a light-emitting functional layer on the connection layer, wherein the light-emitting functional layer includes a plurality of light-emitting units, wherein each of the light-emitting units is electrically connected with a conductive structure in at least one via hole, and an orthographic projection of the via hole on a carrying surface of the connection layer is disposed outside an orthographic projection of a light-emitting region of a corresponding light-emitting units on the carrying surface.

### BRIEF DESCRIPTION OF THE DRAWINGS

To describe the technical solutions in the embodiments of the present disclosure more clearly, the following briefly introduces the accompanying drawings required for describing the embodiments. Apparently, the accompanying drawings in the following description show merely some embodiments of the present disclosure, and a person of ordinary skill in the art may still derive other drawings from these accompanying drawings without creative efforts.

FIG. 1 is a schematic structural diagram of film layers of a display substrate according to some embodiments of the present disclosure;

FIG. 2 is a schematic plan view of a display substrate according to some embodiments of the present disclosure;

FIG. 3 is a schematic structural diagram of film layers of another display substrate according to some embodiments of the present disclosure;

FIG. 4 is a schematic plan view of a display substrate according to some embodiments of the present disclosure;

FIG. 5 is a schematic diagram of a display panel according to some embodiments of the present disclosure; and

FIG. 6 is a flowchart of a method for preparing a display substrate according to some embodiments of the present disclosure.

The symbols in the figures are illustrated as follows:
10, display substrate;
11, array substrate; 12, connection layer; 120, via hole; 121, tungsten structure;
20, light-emitting functional layer; 21, pixel definition layer; 210, opening; 211, first silicon oxide layer; 212, silicon nitride layer; 213, second silicon oxide layer; 22, light-emitting unit; 221, anode layer; 222, light-emitting layer; 223, current spreading layer; 224, cathode layer; 200, isolation groove; 201, first portion; 202, second portion; 203, groove segment;
30, color film layer;
40, touch layer;
50, packaging layer;
A1, light-emitting region; A2, pixel region;
X, first direction; and Y, second direction.

### DETAILED DESCRIPTION

For clearer descriptions of the objectives, technical solutions, and advantages of the present disclosure, embodiments of the present disclosure are described in detail hereafter with reference to the accompanying drawings.

Unless otherwise defined, technical or scientific terms used herein shall have the ordinary meaning as understood by those of ordinary skill in the art to which the present disclosure belongs. The terms “first”, “second”, “third”, and other similar words, as used in the specification and in the claims of the patent application of the present disclosure, do not indicate any order, quantity, or importance, but are merely defined to distinguish different components. Likewise, the terms “a”, “an”, or other similar words do not indicate a limitation of quantity, but rather the presence of at least one. The terms “include”, “comprise”, or other similar words indicate that the elements or objects stated before “include” or “comprise” encompass the elements or objects and equivalents thereof listed after “include” or “comprise”, but do not exclude other elements or objects. The terms “connecting”, “connected”, or other similar words are not limited to physical or mechanical connections, but may include electrical connections, whether direct or indirect. The terms “up”, “down”, “left”, “right”, “top”, “bottom”, and the like are merely defined to indicate relative positional relationships. In the case that the absolute position of a described object changes, the relative position relationship may also change accordingly.

In the related art, the via holes are disposed below the light-emitting regions of the light-emitting units of the light-emitting functional layer. In the case that the thickness of conductive structures in the via holes does not meet the requirements after processing, the thickness of the anode layer above the via holes is influenced, and thus the reflectance of the anode layer is influenced, such that the improvement of the light-emitting effect of the light-emitting functional layer is not facilitated.

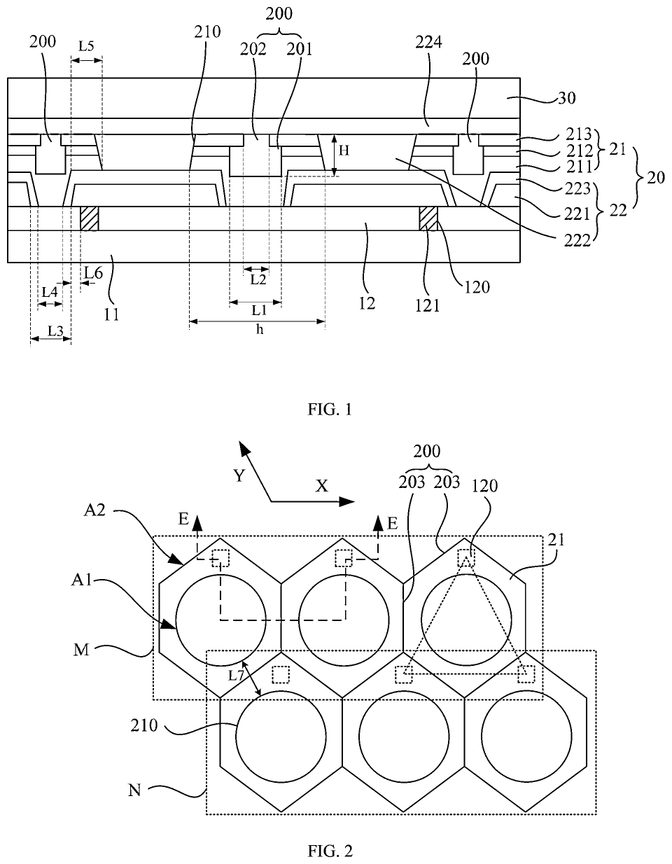

FIG. 1 is a schematic structural diagram of film layers of a display substrate according to some embodiments of the present disclosure. FIG. 2 is a schematic plan view of a display substrate according to some embodiments of the present disclosure. The structure of the film layers in FIG. 1 is a schematic cross-sectional view at section line EE in FIG. 2.

As shown in FIG. 1, the display substrate includes: an array substrate 11, a connection layer 12, and a light-emitting functional layer 20. The connection layer 12 is disposed between the array substrate 11 and the light-emitting functional layer 20.

As shown in FIG. 1 and FIG. 2, the connection layer 12 is provided with a plurality of via holes 120, the light-emitting functional layer 20 includes a plurality of light-emitting units 22, each of the light-emitting units 22 is electrically connected with a conductive structure in at least one via hole 120, and an orthographic projection of the via hole 120 on a carrying surface of the connection layer 12 is disposed outside an orthographic projection of a light-emitting region A1 of a corresponding light-emitting unit 22 on the carrying surface.

The carrying surface is a surface, facing towards the light-emitting functional layer 20, of the connection layer 12, that is, a surface, carrying the light-emitting functional layer 20, of the connection layer 12.

The display substrate is provided with a display region and a non-display region surrounding the display region. The display region includes a plurality of light-emitting units 22, and an image is displayed by controlling the plurality of light-emitting units 22 to emit light.

The display substrate according to some embodiments of the present disclosure includes an array substrate 11, a connection layer 12, and a light-emitting functional layer 20. The connection layer 12 is provided with via holes 120, and the array substrate 11 is connected with the light-emitting functional layer 20 through the via holes 120, such that the light-emitting functional layer 20 can be controlled to emit light through the array substrate 11. The light-emitting functional layer 20 includes a plurality of light-emitting units 22. Light-emitting regions A1 of the light-emitting units 22 are portions configured to emit light, and the via holes 120 are disposed outside the light-emitting regions A1, such that the via holes 120 are not opposite to the light-emitting regions A1. In this way, in the case that the thickness processing of the conductive structures in the via holes 120 does not meet the requirements, the thickness of the anode layer 221 in the light-emitting functional layer 20 is not influenced, and the reflection effect of the anode layer 221 is ensured, such that the light-emitting effect of the light-emitting functional layer 20 is improved.

the array substrate 11 being connected with the light-emitting functional layer 20 through the via holes 120 means that drive circuits in the array substrate 11 and the light-emitting units in the light-emitting functional layer 20 are electrically connected via the conductive structures disposed in the via holes 120.

Exemplarily, each of the light-emitting units 22 is connected with one via hole 120.

In the embodiments of the present disclosure, the array substrate 11 includes a base substrate and a plurality of pixel drive circuits arranged on the substrate in an array.

The array substrate is a thin film transistor (TFT) substrate, and each of the pixel drive circuits on the array substrate at least includes two TFTs configured to control the connected light-emitting units to emit light.

In some embodiments, the array substrate includes a base substrate, an active layer, a gate insulating layer, a gate layer, an interlayer dielectric layer, and a source-drain layer which are sequentially stacked.

In the embodiments of the present disclosure, the base substrate is any transparent substrate, such as a glass substrate, a quartz substrate, a plastic substrate, or other transparent rigid or flexible substrate, which is of a single-layer or multi-layer structure.

Taking the multi-layer structure as an example, the base substrate includes a first polyimide (PI) layer, a first protection layer, a second polyimide (PI) layer, and a second protection layer which are sequentially stacked from bottom to top. Both the two protection layers are configured to protect the PI layer and prevent the PI layer from being damaged by a subsequent process. The second protection layer is also covered with a buffer layer which can block water and oxygen and separate basic ions.

In addition, the base substrate may also be a silicon substrate, such as monocrystalline silicon or high purity silicon. The transistors in the pixel drive circuits described above are integrated into the silicon substrate. For example, the source, the drain, and the gate of each of the transistors are formed in the silicon substrate by a doping process.

Exemplarily, the material for preparing the active layer is amorphous silicon, polycrystalline silicon, a metal oxide semiconductor, or the like; the material for preparing the gate insulating layer is silicon oxide, silicon nitride, or silicon oxynitride, or the like.

Exemplarily, the material for preparing the gate metal layer is a single-layer metal thin film of molybdenum, copper, titanium, or the like, or is a molybdenum layer, an aluminum layer, and a molybdenum layer which are sequentially stacked, or a multi-layer metal thin film of a titanium layer, an aluminum layer, and a titanium layer which are sequentially stacked; the interlayer dielectric layer is made of silicon oxide, silicon nitride, or the like.

Exemplarily, the material for preparing the source-drain metal layer is a single-layer metal thin film of aluminum, molybdenum, copper, titanium, or the like, or is a molybdenum layer, an aluminum layer, and a molybdenum layer which are sequentially stacked, or a multi-layer metal thin film of a titanium layer, an aluminum layer, and a titanium layer which are sequentially stacked.

Exemplarily, the material for preparing the active layer includes low temperature poly-silicon (LTPS), low temperature polycrystalline oxide (LTPO), and the like.

It should be noted that, only the TFT substrate structure provided with a single gate metal layer is illustrated in the embodiments, and the TFT substrate structure may also be a variety of structures such as a double-layer gate metal layer, which is not limited in the embodiments of the present disclosure.

In some embodiments, as shown in FIG. 2, the light-emitting functional layer 20 further includes a pixel definition layer 21. The pixel definition layer 21 includes a plurality of openings 210 spaced apart from each other, the openings 210 are in one-to-one correspondence with the light-emitting units 22, and each of the light-emitting units 22 is disposed in a corresponding opening 210. Each of the openings 210 is configured to define the light-emitting region A1 of the corresponding light-emitting unit 22.

In the embodiments of the present disclosure, the outer outline of the light-emitting region A1 is the outer outline of the opening 210, and the light-emitting unit 22 disposed in the opening 210 emits light through the opening 210 (i.e., the light-emitting region A1).

Each of the pixel drive circuits of the array substrate is electrically connected with at least one light-emitting unit. In this way, the light-emitting units can emit light under the driving of the connected drive circuit.

Exemplarily, as shown in FIG. 1, the anode layer 221 of the light-emitting unit 22 is connected with the source-drain layer of the corresponding drive circuit through the via hole 120.

In some embodiments, as shown in FIG. 1, the light-emitting unit 22 includes an anode layer 221 and a light-emitting layer 222 which are sequentially stacked. The anode layer 221 is disposed on the carrying surface, and the pixel definition layer 21 is disposed on the carrying surface and the surface of the anode layer 221. A portion of the surface of the anode layer 221 is exposed from the opening of the pixel definition layer 21, that is, the edge of the anode layer 221 is sandwiched between the carrying surface and the pixel definition layer 21, and the middle of the anode layer 221 is disposed in the opening. The light-emitting layer 222 is disposed in the opening.

As shown in FIG. 1, the via holes 120 are connected with the anode layer 221, and orthographic projections of the via holes 120 on the carrying surface are disposed in an orthographic projection of the pixel definition layer 21 on the carrying surface.

As the light-emitting layer 222 is disposed in the opening of the pixel definition layer 21 and the light-emitting layer 222 is a portion configured to emit light in the light-emitting unit 22, the opening of the pixel definition layer 21 is the light-emitting region A1 of the light-emitting unit 22. The orthographic projections of the via holes 120 on the carrying surface are disposed in the orthographic projection of the pixel definition layer 21 on the carrying surface, such that the via holes 120 are disposed outside the light-emitting regions A1, and the via holes 120 are not opposite to the light-emitting region A1. Therefore, the thickness of the conductive structures in the via holes 120 does not affect the thickness of the anode layer 221 of the light-emitting regions A1, and the uniformity of the thickness of the anode layer is ensured.

Exemplarily, the light-emitting layer 222 includes a hole transport layer (HTL), a hole injection layer (HIL), an electron transport layer (ETL), an electron injection layer (EIL), a hole block layer (HBL), an electron blocking layer (EBL), and a light-emitting material layer.

Exemplarily, the anode layer 221 includes a Ti layer, an A1 layer, and a Ti layer which are sequentially stacked.

In some embodiments, the conductive structure in the via hole 120 is a metal structure. Exemplarily, as shown in FIG. 1, the conductive structure in the via hole 120 is a tungsten structure 121. The source-drain layer of the array substrate 11 is exposed from the via hole 120, and the tungsten structure 121 connects the source-drain layer of the array substrate 11 with the anode layer 221. In addition, the via hole 120 is disposed below the pixel definition layer 21, and the tungsten structure 121 in the via hole is connected with the drive circuit on the array substrate 11.

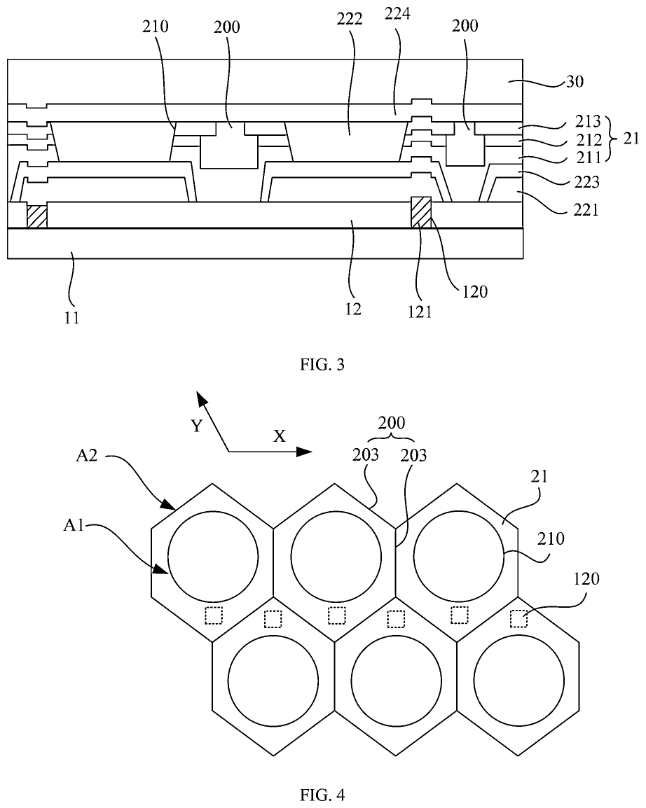

In some embodiments, as shown in FIG. 3, regions of the film layers of the light-emitting functional layer 20 which are opposite to a plurality of the via holes 120 protrude from surfaces, facing away from the carrying surface, of the film layers of the light-emitting functional layer 20, or are recessed from the surfaces, facing away from the carrying surface, of the film layers of the light-emitting functional layer 20.

Referring to the schematic diagram of the via hole 120 on the left side of FIG. 3, in the case that the thickness of the tungsten structure 121 filled in the via hole 120 is smaller than a hole depth of the via hole 120, regions of the film layers of the light-emitting functional layer 20 which are opposite to the plurality of via holes 120 are recessed from the surfaces, facing away from the carrying surface, of the film layers of the light-emitting functional layer 20.

Referring to the schematic diagram of the via hole 120 on the right side of FIG. 3, in the case that the thickness of the tungsten structure 121 filled in the via hole 120 is greater than a hole depth of the via hole 120, regions of the film layers of the light-emitting functional layer 20 which are opposite to a plurality of the via holes 120 protrude from the surfaces, facing away from the carrying surface, of the film layers of the light-emitting functional layer 20.

In the embodiments described above, the height of the film layer of the pixel definition layer outside the light-emitting regions is increased by the tungsten structures 121. In this way, in the process of depositing the light-emitting layer 222 on the pixel definition layer 21, the raised pixel definition layer 21 can more easily separate the light-emitting layer 222, such that the light-emitting layer is divided into a plurality of spaced and insulated light-emitting layers 222.

Exemplarily, as shown in FIG. 3, the light-emitting unit 22 further includes a cathode layer 224. The cathode layer 224 is disposed on the surface, facing away from the carrying surface, of the light-emitting layer 222 and on the surface, facing away from the carrying surface, of the pixel definition layer 21. Referring to the schematic diagram of the via hole 120 on the right side of FIG. 3, regions of the cathode layer 224 which are opposite to a plurality of the via holes 120 protrude from a surface, facing away from the carrying surface, of the cathode layer 224. Referring to the schematic diagram of the via hole 120 on the left side of FIG. 3, regions of the cathode layer 224 which are opposite to a plurality of the via holes 120 are recessed from a surface, facing away from the carrying surface, of the cathode layer 224. In this way, the cathode layer is formed in a wavy shape and is not easy to break.

In some embodiments, as shown in FIG. 1, the light-emitting unit 22 further includes a current spreading layer 223. The current spreading layer 223 is disposed between the anode layer 221 and the light-emitting layer 222.

By disposing the current spreading layer 223 between the anode layer 221 and the light-emitting layer 222, the current transferred from the anode layer 221 can be spread over the entire surface of the light-emitting layer 222, such that the light-emitting efficiency of the light-emitting layer 222 is improved.

Exemplarily, the current spreading layer 223 is an indium tin oxide (ITO) layer or an indium zinc oxide (IZO) layer.

In the embodiments of the present disclosure, as shown in FIG. 1, the anode layers 221 of different light-emitting units 22 are spaced apart from each other, and the current spreading layer 223 is disposed on a surface, facing away from the substrate, of the anode layer 221 and extend to a side surface of the anode layer 221 and the carrying surface. In this way, by coating the anode layer 221 through the current spreading layer 223, the current transmitted to the side surface of the anode layer 221 can be spread to the light-emitting layer 222 through the current spreading layer 223, such that the light-emitting effect of the light-emitting layer 222 is improved.

In some embodiments, the orthographic projection of the via hole 120 on the carrying surface is disposed in an orthographic projection of the pixel definition layer 21 on the carrying surface, the orthographic projection of the via hole 120 on the carrying surface is disposed in an orthographic projection of the current spreading layer 223 on the carrying surface, and referring to FIG. 1, a first distance L6 is arranged between the via hole 120 and a side surface of the current spreading layer 223 facing the anode layer 221. In this way, the current spreading layer 223 is prevented from tilting up on the side surface of the anode layer 221 as much as possible. For example, the first distance L6 is 0.5-0.8 μm. In the embodiments described above, the anode layer 221 and the current spreading layer 223 are prepared by the following method: Firstly, a Ti layer, an Al layer, and a Ti layer are sequentially deposited on the carrying surface; then, the deposited metal film layers are etched to obtain a plurality of anode layers 221 spaced apart from each other; subsequently, an ITO layer is deposited on the anode layer 221 and the carrying surface; and finally, the ITO layer is etched to obtain a current spreading layer 223 coating the anode layer 221. Compared with the mode of depositing all the film layers at one time and then etching, the anode layer can be well coated with the current spreading layer through the mode of depositing and etching twice, and the coating performance of the current spreading layer on the anode layer is improved.

In the embodiments of the present disclosure, as shown in FIG. 1, a minimum pitch L3 between two adjacent anode layers 221 is not less than 0.7 μm. A minimum pitch L4 between the current spreading layers 223 on the two adjacent anode layers 221 is not less than 0.4 μm.

In some embodiments, as shown in FIG. 1, the pixel definition layer 21 includes a first silicon oxide layer 211, a silicon nitride layer 212, and a second silicon oxide layer 213 which are sequentially stacked.

The opening 210 of the pixel definition layer 21 is in an inverted frustum shape. That is, the area of an end, close to the substrate, of an opening of the pixel definition layer 21 is smaller than the area of an end, facing away from the substrate, of the opening of the pixel definition layer 21.

As shown in FIG. 1, the sidewall of the opening of the pixel definition layer 21 is inclined to the carrying surface. In this way, the light emitted from the light-emitting layer 222 can be reflected to a light-emergent side of the display substrate through the sidewall of the opening, such that the luminous output of the display substrate is increased and the light-emitting effect is improved.

In the embodiments of the present disclosure, the light-emitting unit 22 is a white light pixel unit, and the display substrate further includes a color film layer 30. The color film layer 30 is disposed on the light-emitting functional layer 20. The light-emitting functional layer 20 formed by the white pixel unit and the color film layer 30 achieve color display.

The color film layer may include a plurality of color resistance blocks with different colors and black matrixes configured to block light rays. The black matrixes are disposed between the color blocking blocks. The plurality of color resistance blocks of the color film layer include different colors. For example, the color resistance blocks include three colors, which are red, green, and blue, respectively. The color film layer is disposed on one side of the array substrate. In this way, the light-emitting unit can transmit different color resistance blocks of the color film layer to emit light with different colors, such that the color display is achieved.

In some embodiments, as shown in FIG. 1 and FIG. 2, the pixel definition layer 21 is provided with isolation grooves 200. The isolation grooves 200 divide the pixel definition layer 21 into a plurality of pixel regions A2, and each of the pixel regions A2 is provided with one of the light-emitting units 22.

The pixel region A2 includes a light-emitting unit 22 and a portion of the pixel definition layer 21 surrounding the light-emitting unit 22. That is, the outer outline of the pixel region A2 is larger than the outer outline of the light-emitting region A1, and the pixel region A2 surrounds the light-emitting region A1.

As shown in FIG. 2, the isolation grooves 200 are boundary structures of the pixel definition layer 21 to divide the pixel definition layer 21 into a plurality of pixel regions A2.

In the embodiments described above, the light-emitting units 22 of the light-emitting functional layer 20 are all white light pixel units. In this way, the preparation of the light-emitting layer 222 can be completed only by performing evaporation once, such that the preparation efficiency is improved. In the process of depositing the light-emitting layer 222 on the pixel definition layer 21, the light-emitting layer 222 sinks into the isolation grooves 200 in the case that the light-emitting layer is deposited at the positions of the isolation grooves 200 by evaporation, while the light-emitting layer 222 evaporated outside the isolation grooves 200 remains on the surface of the pixel definition layer 21. In this way, the light-emitting layer 222 at the positions of the isolation grooves 200 is torn, such that the light-emitting layer 222 is divided at the positions of the isolation grooves 200 into a plurality of spaced and insulated light-emitting layers 222. By providing the isolation grooves 200 without using a mask structure to evaporate the light-emitting layer 222, the light-emitting layer 222 with a smaller thickness is formed, and the preparation efficiency of the light-emitting layer 222 can be effectively improved.

In some embodiments, as shown in FIG. 1, the isolation groove 200 at least includes a first portion 201 and a second portion 202 which are connected with each other. The first portion 201 and the second portion 202 are sequentially arranged along a direction away from the carrying surface, and a dimension of the first portion 201 in an arrangement direction of two light-emitting units adjacent to the isolation groove 200 is not smaller than a dimension of the second portion 202 in the arrangement direction of the two light-emitting units adjacent to the isolation groove 200.

In the embodiments of the present disclosure, the isolation groove 200 at least includes the first portion 201 and the second portion 202 which are connected with each other. The dimension of the first portion 201 in the arrangement direction of two adjacent light-emitting units is not smaller than the dimension of the second portion 202 in the arrangement direction of the two adjacent light-emitting units. In this way, the dimension of the bottom of the isolation grooves 200 is greater, and after the light-emitting layer 222 sinks into the isolation grooves 200, the space of the light-emitting layer 222 accumulated at the bottom of the isolation grooves 200 is larger, which makes the sunk light-emitting layers 222 not easy to contact with each other, such that the light-emitting layer 222 is ensured to be torn at the positions of the isolation grooves 200 to form a plurality of insulated light-emitting layers 222.

Exemplarily, as shown in FIG. 1, the isolation groove 200 includes a first portion 201 and a second portion 202 which are sequentially disposed along a direction away from the carrying surface. The second portion 202 is connected with the middle of the first portion 201, such that the first portion 201 and the second portion 202 form a stepped groove.

It should be noted that, in some other embodiments, the isolation groove 200 further includes a plurality of portions, such as three and four portions, which are sequentially disposed along the direction away from the carrying surface, which is not limited in the embodiments of the present disclosure.

In some embodiments, as shown in FIG. 1, the groove depth H of the isolation groove 200 is not less than the thickness of the light-emitting layer 222. In the case that the groove depth H of the isolation groove 200 is greater than or equal to the thickness of the light-emitting layer 222, it can be ensured that the light-emitting layer 222 can completely sink into the isolation grooves 200 in the case that the light-emitting layer is evaporated at the positions of the isolation grooves 200, such that the light-emitting layer 222 is ensured to be torn by the isolation grooves 200 to form a plurality of insulated light-emitting layers 222.

In some embodiments, as shown in FIG. 1, an opening width L2 of the isolation groove 200 is 0.2 μm to 0.5 μm.

The opening width L2 of the isolation groove 200 is a width of an end, facing away from the carrying surface, of an opening of the isolation groove 200 in the arrangement direction of the two adjacent light-emitting units 22.

By setting the opening width of the isolation groove 200 in the range described above, it can be avoided that the opening width is set too small to achieve the purpose of tearing and separating the light-emitting layer 222; and it can also be avoided that the opening width is set too large, which results in the distribution of the light-emitting units 22 at large intervals, such that the light-emitting units 22 are sparsely distributed to influence the light-emitting effect of the light-emitting functional layer 20.

Exemplarily, the width of the second portion 202 of the isolation groove 200 in the arrangement direction of the two adjacent light-emitting units 22 is the opening width of the isolation grooves 200, and the opening width L2 of the isolation grooves 200 is 0.3 μm.

In some embodiments, a maximum width L1 of the isolation groove 200 is 0.5 μm to 1 μm.

The maximum width L1 of the isolation groove 200 is a width of the isolation groove 200 at an end proximal to the carrying surface in the arrangement direction of the two adjacent light-emitting units 22.

By setting the maximum width of the isolation groove 200 in the range described above, it can be avoided that the maximum width of the isolation groove 200 is set too small to achieve the purpose of separating the light-emitting layer 222 sunk in the isolation grooves 200; and it can also be avoided that the maximum width of the isolation groove 200 is set too large, which reduces the strength of the pixel definition layer 21.

Exemplarily, as shown in FIG. 1, the width of the first portion 201 of the isolation groove 200 in the arrangement direction of the two adjacent light-emitting units 22 is the maximum width L1 of the isolation groove 200. The maximum width L1 of the isolation groove 200 is 0.8 μm.

It should be noted that, in the case that the light-emitting unit includes light-emitting units of a plurality of colors, for example, in the case that the light-emitting unit includes light-emitting units of three colors, which is a red light-emitting unit, a green light-emitting unit, and a blue light-emitting unit, respectively, no isolation groove is required to be disposed on the pixel definition layer.

In some embodiments, as shown in FIG. 1, a pitch h between two adjacent light-emitting units 22 is 1 μm to 1.5 μm.

In the embodiments of the present disclosure, the pitch between the two adjacent light-emitting units 22 is a maximum distance between openings of two adjacent pixel definition layers 21.

By setting the pitch between the two adjacent light-emitting units 22 in the range described above, it can be avoided that the pitch between the two adjacent light-emitting units 22 is set too small to leave sufficient space to form the isolation groove 200; and it can also be avoided that the pitch between the two adjacent light-emitting units 22 is set to large, such that the light-emitting units 22 are sparsely distributed to influence the light-emitting effect of the light-emitting functional layer 20.

Exemplarily, a pitch h between the two adjacent light-emitting units 22 is 1.3 μm.

It should be noted that, in some other embodiments, a minimum distance between the openings of the two adjacent pixel definition layers 21, or a mean value of a maximum distance and the minimum distance between the openings of the two adjacent pixel definition layers 21 may also be used to indicate the pitch between the two adjacent light-emitting units 22, which is not limited in the embodiments of the present disclosure.

In some embodiments, as shown in FIG. 1, a maximum length L5 of a portion of the pixel definition layer 21 on the anode layer 221 in a direction from an edge of the anode layer 221 to the middle of the anode layer 221 is not less than 0.2 μm.

By setting the maximum length of a portion of the film layers of the pixel definition layer 21 overlapped on the anode layer 221 in the range described above, it can be avoided that the portion of the film layers of the pixel definition layer 21 overlapped on the anode layer 221 is too small to achieve the purpose of supporting the pixel definition layer 21; it can also be avoided that the portion of the film layers of the pixel definition layer 21 overlapped on the anode layer 221 is too large, such that the openings of the pixel definition layer 21 are narrowed to influence the light-emitting effect of the light-emitting units 22.

Exemplarily, the maximum length of the portion of the pixel definition layer 21 on the anode layer in the direction from the edge of the anode layer 221 to the middle of the anode layer 221 is 0.3 μm.

In some embodiments, as shown in FIG. 2, the plurality of light-emitting units 22 are disposed along a first direction X and a second direction Y. The first direction X is intersected with the second direction Y.

Exemplarily, as shown in FIG. 2, the first direction X is a horizontal direction illustrated in FIG. 2, and a non-zero included angle is present between the first direction X and the second direction Y. For example, the included angle between the first direction and the second direction is 90° to 170°.

As shown in FIG. 2, the plurality of light-emitting units 22 includes a plurality of first light-emitting unit groups M and a plurality of second light-emitting unit groups N which are sequentially and alternately arranged along the second direction Y, and each of the first light-emitting unit groups M and the second light-emitting unit groups N includes a plurality of light-emitting units 22 spaced apart from each other along the first direction X.

As shown in FIG. 2, a plurality of via holes 120 corresponding to the first light-emitting unit group M are disposed on the same side of the first light-emitting unit group M, and a plurality of via holes 120 corresponding to the second light-emitting unit group N are disposed on the same side of the second light-emitting unit group N.

By disposing the plurality of via holes 120 regularly and orderly on the same side of the first light-emitting unit group M or the second light-emitting unit group N, the processing and preparation are facilitated.

In some embodiments, as shown in FIG. 2, in adjacent first light-emitting unit group M and second light-emitting unit group N, the via holes 120 corresponding to the first light-emitting unit group M and the via holes 120 corresponding to the second light-emitting unit group N are disposed at both sides of the first light-emitting unit group M or the second light-emitting unit group N. For example, the via holes 120 corresponding to the first light-emitting unit group M and the via holes 120 corresponding to the second light-emitting unit group N are disposed at both sides of A1 of the first light-emitting unit group M.

Exemplarily, as shown in FIG. 2, a row of via holes 120 corresponding to the first light-emitting unit group M is disposed above the first light-emitting unit group M. A row of via holes 120 corresponding to the second light-emitting unit group N is disposed above the second light-emitting unit group N. That is, the two rows of via holes 120 are disposed at upper and lower sides of the first light-emitting unit group M.

Exemplarily, in some other embodiments, a row of via holes 120 corresponding to the first light-emitting unit group M is disposed below the first light-emitting unit group M. A row of via holes 120 corresponding to the second light-emitting unit group N is disposed below the second light-emitting unit group N. That is, the two rows of via holes 120 are disposed at upper and lower sides of the second light-emitting unit group N.

The via holes 120 are all arranged at the geometric centers of the openings in the related art, while in the embodiments of the present disclosure, the via holes 120 are integrally translated from the geometric centers of the openings to a side outside the openings. In this way, the via holes 120 are integrally translated and arranged on the same side of the first light-emitting unit group or the second light-emitting unit group, which is beneficial to uniformity of display effect; and the via holes 120 are integrally translated, such that the original mask structure can still be used to prepare the via holes 120, and the integral offset function can be achieved in the manufacturing process, saving the preparation cost.

Exemplarily, as shown in FIG. 2, at least a portion of a group of via holes 120 corresponding to the first light-emitting unit group M and a group of via holes 120 corresponding to the second light-emitting unit group N is distributed on a straight line with a portion of the isolation grooves 200. Such an arrangement mode can also effectively reduce the occupied area of the arrangement of the via holes.

For example, as shown in FIG. 2, the pixel region A2 is in a hexagonal shape, and the isolation groove 200 includes a plurality of groove segments 203. The plurality of groove segments 203 are connected to form at least one pixel region A2. That is, side edges of the pixel region A2 are all groove segments 203 of the isolation groove 200. A plurality of groove segments 203 in the isolation groove 200 which are perpendicular to the first direction X are provided with corresponding via holes 120. The geometric centers of the via holes 120 corresponding to the groove segments 203 are disposed on extension lines of the corresponding groove segments 203.

In some embodiments, in the same pixel region A2, the via hole 120 is disposed between the isolation groove 200 and the light-emitting region A1. Exemplarily, as shown in FIG. 2, at least a portion of a group of via holes 120 corresponding to the first light-emitting unit group M and/or a group of via holes 120 corresponding to the second light-emitting unit group N is disposed between the isolation groove 200 and the light-emitting region A1.

In some embodiments, in the same pixel region A2, a minimum distance between the geometric center of the via hole 120 and the light-emitting region A1 is smaller than a minimum distance between the geometric center of the via hole 120 and the isolation groove 200. For example, in the first light-emitting unit group M, a distance between the via hole 120 and the corresponding light-emitting region A1 is smaller than a distance between the via hole 120 and the isolation groove 200. In this way, it is beneficial for a connecting line from the via hole to the light-emitting region to be shorter, and it is beneficial to avoiding a distance between the via hole 120 and the isolation groove 200 being too proximal, which results in a poor process (for example, the isolation groove 200 is easy to overetch to influence the connecting line from the via hole, resulting in short circuit or breakage).

In some embodiments, as shown in FIG. 2, in two adjacent pixel regions A2 in the second direction Y, a distance between the geometric centers of the two via holes 120 is greater than a pitch L7 between the two light-emitting regions A1. Exemplarily, a distance between at least one of the via holes 120 corresponding to the first light-emitting unit group M and the via hole 120 of the adjacent (for example, left and right sides along the X direction) second light-emitting unit group N is greater than the pitch L7 between the two adjacent light-emitting regions A1. By the design, the structuring of the routing layout and the improvement of the yield are facilitated.

Exemplarily, as shown in FIG. 2, at least one of the via holes 120 corresponding to the first light-emitting unit group M is at an equal distance from two via holes 120 of the adjacent (for example, left and right sides along the X direction) second light-emitting unit group N, and the three via holes 120 form a regular triangle structure (see a triangular dashed box illustrated in FIG. 2). By the design, the structuring of the routing layout and the improvement of the yield are facilitated.

In some other embodiments, FIG. 4 is a schematic plan view of a display substrate according to some embodiments of the present disclosure. As shown in FIG. 4, in adjacent first light-emitting unit group M and second light-emitting unit group N, the via holes 120 corresponding to the first light-emitting unit group M and the via holes 120 corresponding to the second light-emitting unit group N are disposed between the first light-emitting unit group M and the second light-emitting unit group N.

A group of via holes 120 corresponding to the first light-emitting unit group M and a group of via holes 120 corresponding to the second light-emitting unit group N, which are disposed between the two light-emitting unit groups, are also spaced apart from each other.

Exemplarily, as shown in FIG. 4, the group of via holes 120 corresponding to the first light-emitting unit group M is distributed on one straight line, and the group of via holes 120 corresponding to the second light-emitting unit group N is distributed on another straight line. In this way, the two groups of via holes 120 are distributed on two straight lines in a staggered manner, and the two sets of via holes 120 form a continuous W shape together.

The group of via holes distributed on one straight line means that the geometric centers of the via holes are distributed along the same straight line.

As shown in FIG. 4, in the case that a pitch between the two straight lines corresponding to the two groups of via holes is not greater than the dimension of the via holes in the arrangement direction of the two straight lines, a partial region overlap of the two groups of via holes presents in an extending direction. Such an arrangement mode can also effectively reduce the occupied area of the arrangement of the via holes.

In the embodiments of the present disclosure, as shown in FIG. 4, the via holes 120 are disposed between the adjacent first light-emitting unit group M and second light-emitting unit group N, and the two groups of via holes 120 of the two groups of light-emitting units 22 are arranged in a staggered manner to form a continuous W shape. The advantage of the distribution mode of the via holes 120 is that the conductive structures in the via holes 120 can be also concentrated on one side of the light-emitting units 22, such that the occupation of other regions in the pixel definition layer 21 is reduced, and it is convenient to provide more space for the arrangement of light-emitting units 22.

It should be noted that, in some other embodiments, the group of via holes 120 corresponding to the first light-emitting unit group M and the group of via holes 120 corresponding to the second light-emitting unit group N are distributed on the same straight line. In this way, the two sets of via holes 120 together form a linear shape. In the distribution mode of the via holes 120, the conductive structures in the via holes 120 can also be concentrated on one side of the light-emitting units 22, such that the occupation of other regions in the pixel definition layer 21 is reduced, and it is convenient to provide more space for the arrangement of light-emitting units 22.

In the embodiments of the present disclosure, the pitch between the via holes 120 is larger in the case that the two sets of via holes 120 are arranged to form a continuous W shape together, than in the case that the two sets of via holes 120 are arranged to form a linear shape together. In this way, the precision requirements of the mask structure used in the etching of the via holes are lower, such that the preparation difficulty can be effectively reduced.

Exemplarily, as shown in FIGS. 2 and 4, the pixel region A2 of the pixel definition layer is in a hexagonal shape.

Exemplarily, as shown in FIG. 4, at least a portion of the via holes 120 corresponding to the first light-emitting unit group M and/or the via holes 120 corresponding to the second light-emitting unit group N are distributed on one straight line with a portion of the isolation grooves 200. Such an arrangement mode can also effectively reduce the occupied area of the arrangement of the via holes.

For example, as shown in FIG. 4, the pixel region A2 is in a hexagonal shape, and the isolation groove 200 includes a plurality of groove segments 203. The plurality of groove segments 203 are connected to form at least one pixel region A2. That is, side edges of the pixel region A2 are all groove segments 203 of the isolation groove 200. A plurality of groove segments 203 in the isolation groove 200 which are perpendicular to the first direction X are provided with corresponding via holes 120. The geometric centers of the via holes 120 corresponding to the groove segments 203 are disposed on extension lines of the corresponding groove segments 203.

In some embodiments, as shown in FIG. 4, the via holes 120 of the adjacent first light-emitting unit group M and second light-emitting unit group N are at an equal distance from the groove segment 203 between the two adjacent light-emitting regions A1.

In some embodiments, as shown in FIG. 4, in two adjacent pixel regions A2 in the second direction Y, a distance between the geometric centers of the two via holes 120 is smaller than a distance between the geometric centers of the two light-emitting regions A1. Exemplarily, as shown in FIG. 4, a distance between at least a portion of the via holes 120 of the first light-emitting unit group M and the via holes 120 of the adjacent second light-emitting unit group N is smaller than a distance between the geometric center of the light-emitting region A1 corresponding to the via hole 120 of the first light-emitting unit group M and the geometric center of the light-emitting region A1 corresponding to the via hole 120 of the adjacent second light-emitting unit group N. By the design, the structuring of the routing layout and the improvement of the yield are facilitated. Exemplarily, as shown in FIG. 4, a distance between at least a portion of adjacent via holes 120 of the first light-emitting unit group M is greater than a distance between the via hole 120 of the first light-emitting unit group M and the via hole 120 of the adjacent second light-emitting unit group N. By the design, the via holes of the first light-emitting unit group M and the via holes 120 of the second light-emitting unit group N are alternately arranged, such that the structuring of the routing layout and the improvement of the yield are facilitated, and the process is simplified.

It should be noted that, in some other embodiments, the pixel region A2 may also be in a polygonal shape, such as a triangular or a quadrilateral shape; or in an arc shape, such as a circular or oval shape; or in an irregular closed shape, which is not limited in the embodiments of the present disclosure.

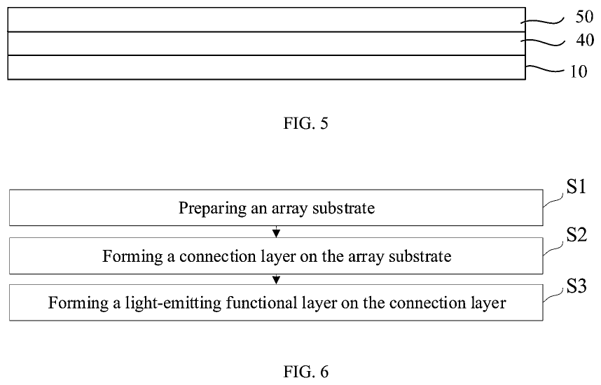

FIG. 5 is a schematic structural diagram of a display panel according to some embodiments of the present disclosure. As shown in FIG. 5, the display panel includes the display substrate 10 described above, a touch layer 40, and a packaging layer 50. The display substrate 10, the touch layer 40, and the packaging layer 50 are sequentially stacked.

The touch layer 40 includes a plurality of touch units and a plurality of touch lines. The plurality of touch units are arranged on the display substrate in an array, and at least a portion of the touch units are disposed in the display region. In some embodiments, all of the touch units are disposed in the display region. In some other embodiments, a portion of the touch units are disposed in the display region, and the other portion of the touch units are disposed in the non-display region. For example, among the plurality of touch units arranged in an array, the outermost touch unit is disposed in the non-display region or a portion of the outermost touch unit is disposed in the non-display region.

The plurality of touch lines are disposed on the display substrate, each of the touch lines is connected with at least one touch control unit, and is configured to electrically connect the connected touch control units with a touch control integrated circuit to connect with the touch control integrated circuit.

The embodiments of the present disclosure provide a display device, including the display panel as described above and a power supply electrically connected with the display panel. The power supply assembly may be a power supply or the like.

The display device may be any product or component with a display function, such as a mobile phone, a tablet computer, a television, a display, a notebook computer, a digital photo frame, and a navigator.

FIG. 6 is a flowchart of a method for preparing a display substrate according to some embodiments of the present disclosure. As shown in FIG. 6, the method for preparing the display substrate includes:

Step S1: An array substrate is prepared.

Step S2: A connection layer is formed on the array substrate.

As shown in FIG. 1, the connection layer is provided with a plurality of via holes.

Conductive structure is deposited in the via hole 120, and is metal structure. Exemplarily, the conductive structure in the via hole 120 is a tungsten structure 121.

Step S3: A light-emitting functional layer is formed on the connection layer.

The light-emitting functional layer 20 includes a plurality of light-emitting units 22. The light-emitting units 22 are in one-to-one correspondence with the via holes 120, and an orthographic projection of the via hole 120 on a carrying surface of the connection layer 12 is disposed outside an orthographic projection of a light-emitting region A1 of the corresponding light-emitting unit 22 on the carrying surface.

The structure of the light-emitting functional layer can be referred to the embodiments illustrated in FIGS. 1 to 4.

The light-emitting functional layer includes a pixel definition layer and a plurality of light-emitting units. The pixel definition layer includes a plurality of openings spaced apart from each other, the openings are in one-to-one correspondence with the light-emitting units, the openings are light-emitting regions, the light-emitting units are disposed in the corresponding openings, and the via holes are connected with the light-emitting units in the corresponding openings. The light-emitting unit includes an anode layer and a light-emitting layer which are sequentially stacked. The anode layer is disposed on the carrying surface, the pixel definition layer is disposed on the carrying surface and the surface of the anode layer, a portion of the surface of the anode layer is exposed from the opening of the pixel definition layer, and the light-emitting layer is disposed in the opening.

In step S3, the pixel definition layer 21 includes a first silicon oxide layer 211, a silicon nitride layer 212, and a second silicon oxide layer 213 which are sequentially stacked.

The pixel definition layer may be obtained using a deposition method by sequentially depositing the first silicon oxide layer, the silicon nitride layer, and the second silicon oxide layer on the surface of the connection layer.

In step S3, the anode layer and the current spreading layer are prepared by the following method: First, a Ti layer, an Al layer, and a Ti layer are sequentially deposited on the carrying surface; then, the deposited metal film layers are etched to obtain a plurality of anode layers spaced apart from each other; sequentially, an ITO layer is deposited on the anode layer and the carrying surface; and finally, the ITO layer is etched to obtain a current spreading layer coating the anode layer.

In step S3, the light-emitting layer includes a hole transport layer, a hole injection layer, an electron transport layer, an electron injection layer, a hole block layer, an electron blocking layer, and a light-emitting material layer.

The light-emitting layer may also be obtained using a deposition method by sequentially depositing the hole transport layer, the hole injection layer, the electron transport layer, the electron injection layer, the hole block layer, the electron blocking layer, and the light-emitting material layer on the surface of the current spreading layer.

The display substrate is prepared by the method described above. The means of preparation used in the preparation methods described above can all be referred to the related art.

The above description does not limit the present disclosure in any way. Although the present disclosure has been disclosed as above through the embodiments, they are not intended to limit the present disclosure. Those skilled in the art can make some changes or modifications to the above disclosed technical contents to give equivalent embodiments of equivalent changes without departing from the scope of the present disclosure. However, any simple alterations, equivalent changes, and modifications made, without departing from the contents of the technical solutions of the present disclosure, on the above embodiments based on the technical essence of the present disclosure shall fall within the scope of the technical solutions of the present disclosure.

1. A display substrate, comprising: an array substrate, a connection layer, and a light-emitting functional layer, wherein the connection layer is disposed between the array substrate and the light-emitting functional layer; and
the connection layer is provided with a plurality of via holes, and the light-emitting functional layer comprises a plurality of light-emitting units, wherein each of the light-emitting units is electrically connected with a conductive structure in at least one via hole, and an orthographic projection of the via hole on a carrying surface of the connection layer is disposed outside an orthographic projection of a light-emitting region of a corresponding light-emitting unit on the carrying surface.

2. The display substrate according to claim 1, wherein the light-emitting functional layer further comprises a pixel definition layer, the pixel definition layer comprising a plurality of openings spaced apart from each other, wherein the openings are in one-to-one correspondence with the light-emitting units, and each of the light-emitting units is disposed in a corresponding opening; and
each of the openings is configured to define the light-emitting region of the corresponding light-emitting unit.

3. The display substrate according to claim 2, wherein the plurality of the light-emitting units are arranged in an array along a first direction and a second direction in an array, the first direction being intersected with the second direction; and
the plurality of the light-emitting units comprise a plurality of first light-emitting unit groups and a plurality of second light-emitting unit groups which are sequentially and alternately arranged along the second direction, and each of the first light-emitting unit groups and the second light-emitting unit groups comprises a plurality of the light-emitting units which are spaced apart from each other in the first direction;
wherein a plurality of the via holes corresponding to the first light-emitting unit group are disposed on a same side of the first light-emitting unit group, and a plurality of the via holes corresponding to the second light-emitting unit group are disposed on a same side of the second light-emitting unit group.

4. The display substrate according to claim 3, wherein in adjacent first light-emitting unit group and second light-emitting unit group,
the via holes corresponding to the first light-emitting unit group and the via holes corresponding to the second light-emitting unit group are disposed at both sides of the first light-emitting unit group or the second light-emitting unit group.

5. The display substrate according to claim 3, wherein in adjacent first light-emitting unit group and second light-emitting unit group,
the via holes corresponding to the first light-emitting unit group and the via holes corresponding to the second light-emitting unit group are disposed between the first light-emitting unit group and the second light-emitting unit group.

6. The display substrate according to claim 3, wherein each of the light-emitting units comprises an anode layer and a light-emitting layer which are sequentially stacked, wherein the anode layer is disposed on the carrying surface, the pixel definition layer is disposed on the carrying surface and the anode layer, a portion of a surface of the anode layer is exposed from the opening of the pixel definition layer, and the light-emitting layer is disposed in the opening; and
the via hole is connected with the anode layer, and the orthographic projection of the via hole on the carrying surface is disposed in an orthographic projection of the pixel definition layer on the carrying surface.

7. The display substrate according to claim 6, wherein each of the light-emitting units further comprises a current spreading layer, wherein the current spreading layer is disposed between the anode layer and the light-emitting layer.

8. The display substrate according to claim 6, wherein a maximum length of a portion of the pixel definition layer on the anode layer in a direction from an edge of the anode layer to a middle of the anode layer is not less than 0.2 μm.

9. The display substrate according to claim 6, wherein isolation grooves are arranged in the pixel definition layer, wherein the isolation grooves divide the pixel definition layer into a plurality of pixel regions, one of the light-emitting units being arranged in each of the pixel regions.

10. The display substrate according to claim 9, wherein each of the isolation grooves at least comprises a first portion and a second portion which are connected with each other, wherein the first portion and the second portion are sequentially arranged along a direction away from the carrying surface, and a dimension of the first portion in an arrangement direction of two light-emitting units adjacent to the isolation groove is not smaller than a dimension of the second portion in the arrangement direction of the two light-emitting units adjacent to the isolation groove.

11. The display substrate according to claim 9, wherein a groove depth of the isolation groove is not less than a thickness of the light-emitting layer.

12. The display substrate according to claim 9, wherein in a same pixel region, the via hole is disposed between the isolation groove and the light-emitting region.

13. The display substrate according to claim 12, wherein in the same pixel region, a minimum distance between a geometric center of the via hole and the light-emitting region is smaller than a minimum distance between the geometric center of the via hole and the isolation groove.

14. The display substrate according to claim 12, wherein in two adjacent pixel regions in the second direction, at least one of the following conditions is satisfied:
a distance between geometric centers of two via holes is greater than a pitch between two light-emitting regions; and
a distance between geometric centers of two via holes is smaller than a distance between geometric centers of two light-emitting regions.

15. (canceled)

16. The display substrate according to claim 1, wherein regions of film layers of the light-emitting functional layer which are opposite to the plurality of via holes protrude from surfaces, facing away from the carrying surface, of the film layers of the light-emitting functional layer, or are recessed from the surfaces, facing away from the carrying surface, of the film layers of the light-emitting functional layer.

17. The display substrate according to claim 1, wherein the conductive structure in the via hole is a tungsten structure.

18. The display substrate according to claim 1, further comprising a color film layer, wherein the light-emitting units are white light pixel units, and the color film layer is disposed on the light-emitting functional layer.

19. A display panel, comprising a display substrate, a touch layer, and a packaging layer, wherein the display substrate, the touch layer, and the packaging layer are sequentially stacked;
wherein the display substrate comprises: an array substrate, a connection layer, and a light-emitting functional layer, wherein the connection layer is disposed between the array substrate and the light-emitting functional layer; and
the connection layer is provided with a plurality of via holes, and the light-emitting functional layer comprises a plurality of light-emitting units, wherein each of the light-emitting units is electrically connected with a conductive structure in at least one via hole, and an orthographic projection of the via hole on a carrying surface of the connection layer is disposed outside an orthographic projection of a light-emitting region of a corresponding light-emitting unit on the carrying surface.

20. A display device, comprising the display panel as defined in claim 19 and a power supply electrically connected with the display panel.

21. A method for preparing a display substrate, comprising:
preparing an array substrate;
forming a connection layer on the array substrate, wherein the connection layer is provided with a plurality of via holes; and
forming a light-emitting functional layer on the connection layer, wherein the light-emitting functional layer comprises a plurality of light-emitting units, wherein each of the light-emitting units is electrically connected with a conductive structure in at least one via hole, and an orthographic projection of the via hole on a carrying surface of the connection layer is disposed outside an orthographic projection of a light-emitting region of a corresponding light-emitting unit on the carrying surface.
